(19) United States
(12) Patent Application Publication
(10) Pub. No.: US 2004/0099958 A1
(43) Pub. Date: May 27, 2004

(54) Crack resistant interconnect module

(76) Inventors: William R. Schildgen, Eau Claire, WI (US); Robin E. Gorrell, Eau Claire, WI (US); Michael D. Holcomb, Cadott, WI (US); William V. Ballard, Altoona, WI (US); Mark F. Sylvester, Landenberg, PA (US)

Correspondence Address: 3M INNOVATIVE PROPERTIES COMPANY, PO BOX 33427, ST. PAUL, MN, 55133-3427, US

(21) Appl. No.: 10/301,124

(22) Filed: Nov. 21, 2002

(51) Int. Cl. H01L 23/48; H01L 23/52; H01L 29/40; H01L 23/12

(52) U.S. Cl. 257/778; 257/738; 257/737; 257/704

(57) ABSTRACT

An interconnect module providing conductive interconnection paths between an integrated chip, a printed wiring board, and at least one layer within the module, incorporating a plurality of alternating dielectric and conductive layers laminated together to form a unitary structure. The module includes a chip attach surface and a board attach surface, that define contact pads for attachment to corresponding pads on the chip and printed wiring board, respectively, by means of solder balls.

### TECHNICAL FIELD

The invention relates to interconnect modules for use with integrated circuit chips having an alternate outer dielectric layer for crack resistance.

### BACKGROUND

Multi-layered interconnect modules are widely used in the semiconductor industry to mechanically support integrated circuit chips and electrically attach the chips to printed wiring boards. Interconnect modules can be configured to support a single chip or multiple chips, and are typically identified by the designation SCM (single chip module) or MCM (multi-chip module).

An interconnect module provides interconnections that serve to electrically couple an integrated circuit chip to signal lines, power lines, and other components carried by a printed wiring board. In particular, the interconnect module provides interconnections that redistribute the densely packed inputs and outputs (I/Os) of the chip to corresponding I/Os on the printed wiring board. In addition to electrical interconnection, an interconnect module typically serves to mechanically couple a chip to a printed wiring board, and may perform other functions such as heat dissipation and environmental protection.

For several reasons, chip package electrical performance is improved when thin dielectric materials are used. Simultaneous switching output (SSO) noise is a major limiting factor for external buss speeds in high-speed computer and networking products. Thin dielectric materials used between power and ground planes offer improved package capacitance, which helps reduce (SSO) noise and cross-talk between signal nets. High performance substrates have a large number of input and output nets relative to lower performing substrates. The large number of nets requires more signal traces on routing layers, and the signal traces must be made very narrow in order to be routed in packages for typical size dies. Typical trace widths range from 20 microns to 50 microns. Thin dielectrics, on the order of 60 microns thick or less, must be used when traces become narrow in order to maintain proper package impedance. The use of thin dielectrics also allows vias, which make electrical connections between the substrate metal layers, to be shorter. Shorter vias have lower inductance, which also decrease package SSO noise. For all of these reasons, thin dielectrics are used in today's high performance packages, and even thinner dielectrics will be required in future chip packages. The use of these thin dielectrics within the package results in an overall package thickness that is substantially thinner than lower performing packages.

The integrated circuit chip packaging industry is confronted with a problem of providing thin, high performance chip packages which are also capable of passing industry standard thermal cycling reliability tests and capable of withstanding thermal cycling in field use due to exposure to weather extremes and power cycling of the end product. Due to their thin, flexible nature and the brittle dielectric materials commonly used in manufacture, thin organic chip packages have been found to be susceptible to developing small cracks in the outer dielectric layers (those closest to the package surfaces) after placing the die into the package and following thermal cycle testing.

After bonding together a low coefficient of thermal expansion (CTE) (approximately 2.6 ppm/° C. for silicon) IC to a relatively thin (less than about 0.75 mm), and therefore flexible, package substrate with a relatively high CTE (greater than 15 ppm/° C.) at elevated temperature, significant intrinsic tensile stresses and strains develop in the package as the substrate cools from a higher temperature to a lower temperature. Some of these stresses and strains may arise directly from bonding the two components together. In such a package substrate, the stresses or strains in a particular region may rise to such a level so as to induce cracks in the dielectric and/or conductor materials making up the substrate. This may occur after either a single low temperature exposure through fracture or after repeated exposures via a fatigue process.

The dielectric cracks have been shown to propagate into the interior of the package with repeated thermal cycling. The cracks can propagate until copper trace layers buried within the substrate are cracked, resulting in electrical opens and failure of the test criteria. The cracks typically initiate in high-stress regions on the outer layers of the package near the edges of metal feature and can propagate throughout the package, leading to electrical opens and thus failure in qualification testing or field use.

U.S. Pat. No. 6,373,717 discloses thermal cycle testing issues and solutions. An IC package is disclosed including information on using an alternate outer layer dielectric. A single material allylated polyphenylene ether (APPE) is claimed for this purpose.

### SUMMARY OF THE INVENTION

The present invention provides a flip-chip IC package that has a reduced or eliminated tendency to develop these stress induced cracks. Integrated circuit packages are provided which offer increased reliability in thermal cycle testing by incorporating a unique dielectric material on as outer dielectric layers. This is accomplished with dielectric materials that have high elongation to break (defined as 1% or greater strain) on the outer layers of the package. The outer layers are selected to present coefficients of thermal expansion (CTE) that promote reliable interconnections with the chip and the printed wiring board (PWB). Preferred materials with required high elongation to break are polyimides, liquid crystal polymer films, and other thin, crack-resistant dielectrics.

More specifically, the present invention provides an interconnect module incorporating a series of alternating dielectric and conductive layers that are laminated together to form a unitary structure. The module has two outer layers and at least one internal layer; internal layer(s) comprise an expanded polytetrafluoroethylene matrix. The laminated interconnect structure may incorporate a number of vias and patterned signal layers that provide conductive interconnection paths between an integrated chip, a printed wiring board, and various layers within the interconnect module. The interconnect module includes chip attach and board attach surfaces that define contact pads for attachment to corresponding pads on the chip and board, respectively, via solder balls.

Flip-chip integrated circuit (IC) packages can be susceptible to cracking in the dielectric layers after assembly of the IC into the package and exposure to low temperatures.

As used herein, the following terms have the defined meanings:

1. The term “conductive” as used herein means electrically conductive.

2. The term “interconnect substrate” as used herein means a substrate to interconnect integrated chips to other electronic devices. The term is equivalent to the terms “package substrate”, “flexible package substrate”, “VCP substrate” and the like.

3. The term “high elongation dielectric material” means a dielectric material that has high elongation to break.

4. The term “high elongation to break” means 1% or greater strain.

5. The term “outer layers”, or “outer dielectric layers”, are the dielectric layers closest to the package surface on the die side and the BGA side.

6. The terms “integrated circuit (IC)”, “die” or “chip are all equivalent terms for the purposes of this disclosure and may be used interchangeably.

### BRIEF DESCRIPTION OF THE DRAWINGS

FIG. 1 is a schematic cross-section of a typical assembled interconnect module.

FIG. 2 shows results of an experimental analysis that shows regions of crack formation.

FIG. 3 is a schematic cross-sectional representation of a seven (7) metal layer interconnect substrate having crack resistant outer dielectric layers.

FIG. 4 is a schematic cross-sectional representation of a five (5) metal layer interconnect substrate having crack resistant outer dielectric layers.

FIG. 5 is a schematic representation of deformation behavior of an interconnect module on cooling.

FIG. 6 is a schematic cross-sectional representation of a seven metal layer interconnect substrate having adhesively attached, crack resistant outer dielectric layers.

FIG. 7 is an FEA model of stress in dielectric as function of distance from pad center/dielectric surface for an IC package that does not contain crack resistant outer dielectric layers.

### DETAILED DESCRIPTION OF THE INVENTION

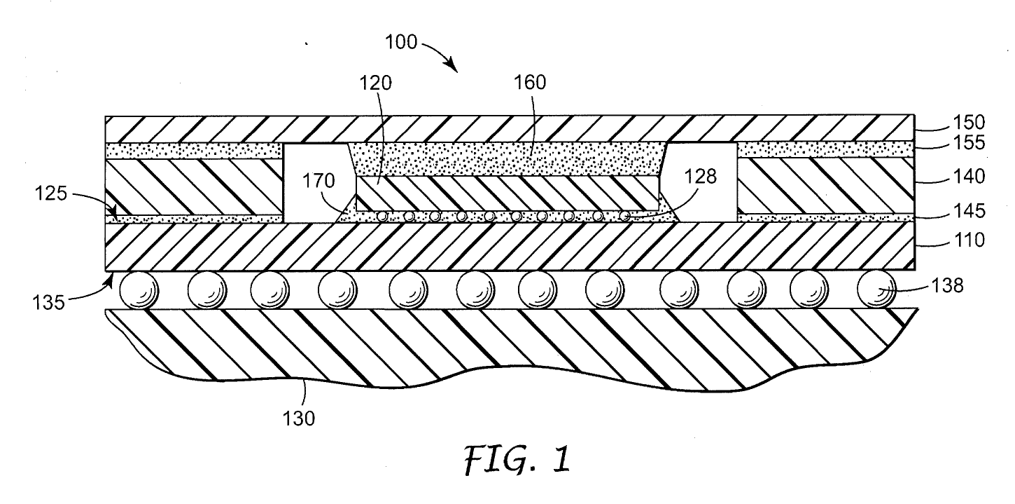

An interconnect module 100, as shown in FIG. 1 and in accordance with the disclosed invention, may incorporate a series of alternating dielectric and conductive layers that are laminated together to form a unitary interconnection substrate 110. The laminated interconnect substrate may incorporate a number of vias and patterned signal layers (not shown) that provide conductive interconnection paths between the chip 120, the printed wiring board 130, and various layers within the interconnect module. The interconnect module includes a chip attach surface 125 and a board attach surface 135 that define contact pads for attachment to corresponding pads on the chip and board, respectively, via solder balls 128, 138 to provide electrical and mechanical connections between the chip and the interconnect substrate and the interconnect substrate and the printed wiring board (PWB). The various layers are selected to present coefficients of thermal expansion (CTE) that promote reliable interconnections with the chip and the PWB. The interconnect module may also include a stiffening member 140 that is bonded by an adhesive 145 to the interconnection substrate 110 on the chip attach surface 125 such that the chip is centered within the stiffening member. An underfill adhesive 170 may be placed between the die attach surface 125 of the interconnect substrate 110 and the bottom side of the chip, thus encapsulating the die attach solder balls 128. Finally, a lid assembly 150 may be bonded by an additional adhesive layer 155 to the topside of the stiffening member. It is possible that a thermally conductive adhesive or elastomer 160 material will be interposed between the top surface of the chip 120 and the lid assembly 150 to assist in dissipating heat generated by the die during operation.

After bonding together a low coefficient of thermal expansion (CTE) (of about 2.6 ppm/° C. for silicon) IC chip 120 to a relatively thin (less than 0.75 mm), and therefore flexible, package substrate 110 with a relatively high CTE (greater than 15 ppm/° C.) at elevated temperature, significant intrinsic tensile stresses and strains develop in the package as the substrate cools to a lower temperature. Some of these may arise directly from the bonding of the two components together. Others may arise from constraining or partially constraining the package substrate from flexing in response to these direct intrinsic stresses or strains. Such constraints can occur when using a stiffening member 140 in the package such as a ring or a lid assembly 150.

In such a package substrate, the stresses or strains in a particular region may rise to such a level so as to induce cracks in the dielectric and/or conductor materials making up the substrate. This may occur after either a single low temperature exposure through fracture or repeated exposures via a fatigue process.

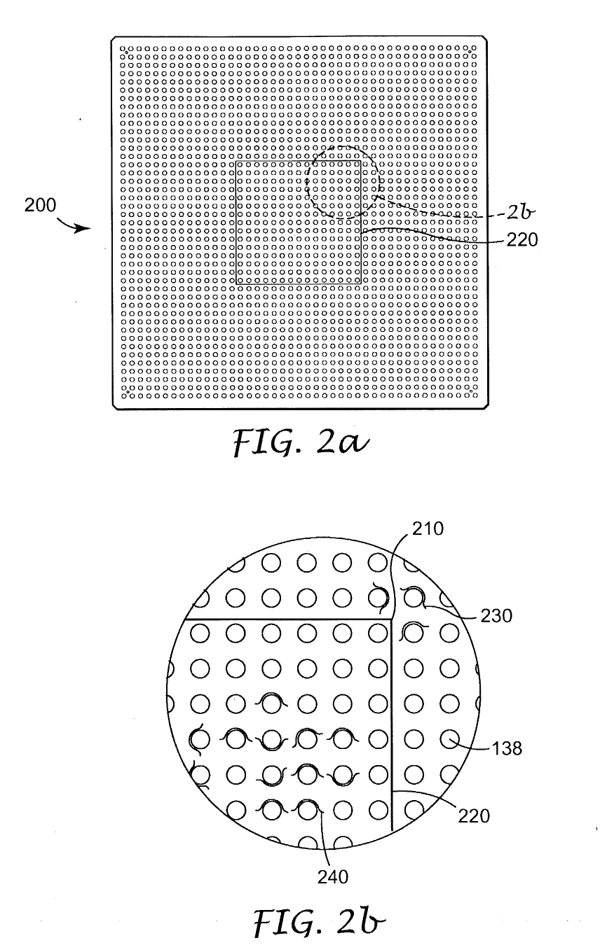

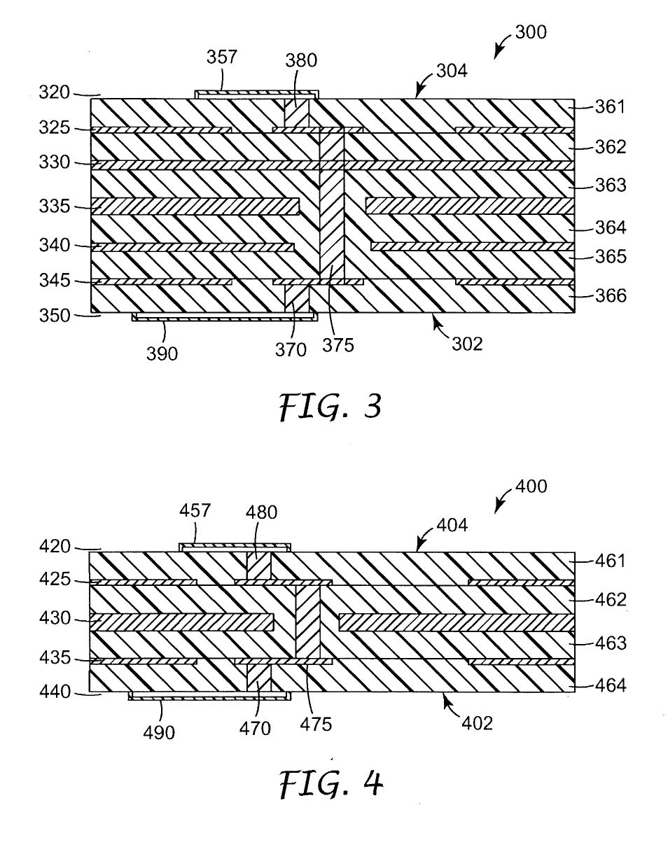

Cracks have been found to form in two regions in interconnect module parts on thermal cycling between +125° C. and −40° C. or −55° C. FIG. 2a and 2b show a map of the location of where cracks form on a BGA interconnect module 200. FIG. 2b is an expanded view of the gray circular region in FIG. 2a. The figure shows an array of solder ball pads 240 on the BGA side of the substrate for a given interconnect module. The first region is just outside of the die comers 210 where the edge of the die 220 is shown by the dark line, and in some extreme cases also running down along the edge of the die 220. The presence of a crack 230 is indicated at bondpads 138 in close proximity to the corner of the die 210. The second region is underneath the die 240, represented by the outline of the edge of the die 220 in the figure as shown by the dark line. Experimental evidence indicates that the cracks form by a classic fatigue process. The cracks universally are initiated at the edge of a metal feature, most commonly a ball grid array (BGA) pad (390 in FIG. 3 and 490 in FIG. 4) on the BGA surface of the interconnect module (302 in FIG. 3 and 402 in FIG. 4) at metal layer 350 in FIG. 3 or metal layer 440 in FIG. 4. The cracks propagate into the dielectric until they reach a solid metal plane such as the power planes in FIG. 3 or the “core” plane 430 in FIG. 4. The planes act as “crack stoppers” because of the intrinsically higher toughness of copper compared to the dielectric material. If the growing dielectric crack encounters a signal trace on a metal layer prior to a plane layer, the trace may crack, forming an electrical open.

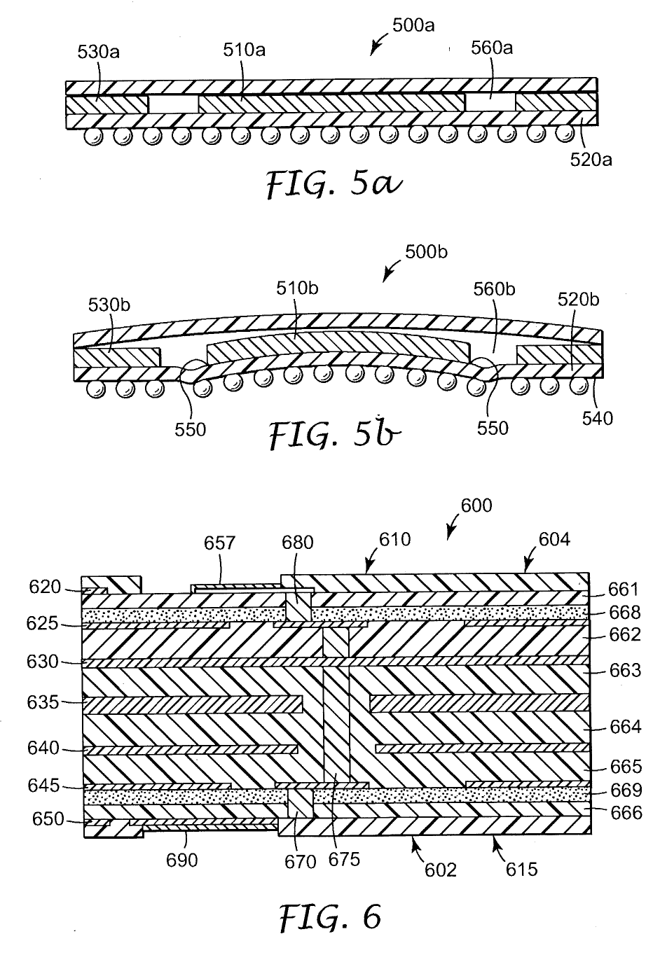

Die corner cracks form primarily from the mechanical constraint imposed by the stiffener ring and lid. As shown in FIG. 5, at elevated temperature, e.g. close to that used to gel and cure the various adhesive materials during the assembly process, the assembled package 500 is in a mostly stress-free state. When cooled to a lower temperature, the mismatch in CTE between the die 510 and other components of the assembled package, particularly between the die and the interconnect substrate 520, causes the package to attempt to assume a concave downward shape. However, the stiffener ring 530 prevents this from happening, instead holding the region of the substrate that it covers in a planar shape. The transition between the concave downward profile of the region under the die and the largely flat profile under the stiffener occurs in the gap between the die and stiffener as shown schematically in FIG. 5. The change in shape over a short distance results in tensile bending strains developing on the BGA side 540 of the substrate. This is particularly true in the regions near the die comers 550 as there is a simultaneous curvature in both the x and y directions.

The more abrupt the change in shape, the higher the strain that will exist at the die corners and in the gap 560 between the die 510 and stiffener ring 530. Conversely, if the change in shape can be made to occur more gradually, the strain will be reduced. Therefore, one action that can be taken to mitigate the problem is to increase the spacing between the die and stiffener ring.

In an effort to support ever increasing switching speeds required for today's computers and networking devices, it has now been discovered that a chip package substrate which offers improved reliability in thermal cycle testing, while maintaining superior electrical performance. The outer layer(s) of dielectric for organic chip package substrates are formed from a material that is resistant to the formation of cracks in thermal cycle testing. Use of these outer layer dielectrics allows high performance packages, which are by nature thin and less susceptible to electrical opens in thermal cycle testing caused by dielectric cracking, to pass industry standard thermal cycle testing intended to mimic long term use in the field.

Chip package electrical performance is improved when thin dielectric materials are used. High performance substrates have a large number of input and output nets relative to lower performing substrates. The large number of nets requires more signal traces on routing layers, and the signal traces must be made very narrow in order to be routed in packages and die of typical size. Typical trace widths range from about b 20 microns to about 50 microns. Thin dielectrics, on the order of about 60 microns thick or less, must be used when traces become narrow in order to maintain proper package impedance. The use of thin dielectrics also allows vias, which make electrical connections between the substrate metal layers, to be shorter. Shorter vias have lower inductance, which also decreases package SSO noise. For all of these reasons, thin dielectrics are used in today's high performance packages, and even thinner dielectrics will be required in future chip packages. The use of these thin dielectrics within the package results in an overall package thickness that is substantially thinner than lower performing packages.

The integrated circuit chip packaging industry is confronted with a problem of providing thin, high performance chip packages which are also capable of passing industry standard thermal cycling reliability tests and capable of withstanding thermal cycling in field use due to exposure to weather extremes and power cycling of the end product. Due to their thin, flexible nature and the brittle dielectric materials commonly used in manufacture, thin organic chip packages have been found to be susceptible to the development of small cracks in the outer dielectric layers after assembly of the die to the package and following thermal cycle testing. The dielectric cracks have been shown to propagate into the interior of the package with repeated thermal cycling. The cracks can propagate until copper trace layers buried within the substrate are cracked, resulting in electrical opens and failure of the test criteria. Crack formation is particularly evident when packages are cycled at −40° C. or −55° C. to +125° C. for 1000 or 1500 cycles, the industry standard thermal cycling specifications for “component level” or “1^{st} level” thermal cycle testing.

These outer dielectric layer cracks primarily form in two locations on the bottom layer (the side opposite the die) of the substrate: at the die comers and under the center of the die. The dielectric cracks are generally formed coincident with the edges of metal features, most typically at the edges of ball grid array (BGA) pads located on the bottom substrate layer. The root cause of the dielectric cracking is the mismatch in the coefficient of thermal expansion (CTE) between the die, with a CTE of approximately 2.6 ppm/° C., and the substrate, which can have variable CTE depending on the materials of construction, but is most often 18 ppm/° C. or greater. Though the root cause of the cracking at both locations is the CTE mismatch, the failure mechanisms differ between the cracks found in the die comers and those found under the die.

At the die comers, the CTE mismatch causes the substrate to bend between the die and the stiffener ring, which is a relatively thick (0.6 mm to 0.8 mm) copper component used to make handling of thin substrates easier during assembly. Substrate bending is at a maximum at the low end of the thermal cycle temperature range. The ball grid array pads on the bottom layer of the substrate concentrate the stress due to bending in the die comers. The stress can exceed the critical stress necessary for fracture in the dielectric materials commonly used to manufacture chip packages. These materials are often composites of thermosetting resins (such as epoxy or cyanate ester) and ceramic fillers, and are relatively brittle in nature, with low elongation to break.

At locations under the die center, the CTE mismatch between the die and the substrate causes in plane stresses to develop. As in the die comers, these stresses can exceed the fracture strengths of the commonly used outer layer dielectric materials, particularly when BGA pads are present to act as stress concentrators, and can cause dielectric cracks to develop and grow with thermal cycling until underlying traces are cracked.

Chip package substrates manufactured for lower performance applications have tended to be 1.0 mm or more thick and are not subject to substantial bending caused by CTE mismatch. Such thick substrates are therefore less susceptible to the development of dielectric cracks and electrical opens on thermal cycle testing. Dielectric cracks become a problem only with thin, high performance substrates less than 1.0 mm thick.

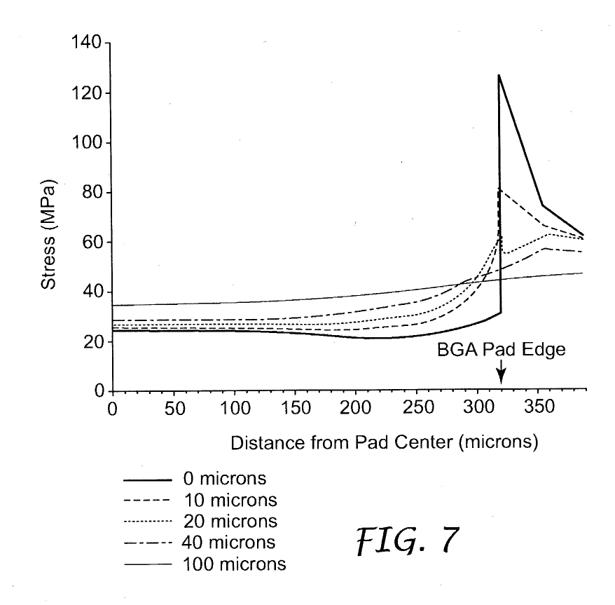

The present invention is an integrated circuit package that offers improved reliability in thermal cycle testing by incorporating a crack resistant dielectric material on the outer layers. Finite element modeling of the stresses in the outer layer dielectric of a thin substrate has shown the region of maximum stress to be highly localized at the BGA pad edges. This is true in both the x-y and z directions. FIG. 7 illustrates the stress as a function of horizontal distance from the pad center and vertical distance from the dielectric surface.

Study of this model and knowledge of the critical stress necessary to initiate cracks in a given material suggests that replacing the outermost dielectric layer with a crack resistant material as thin as 10 microns to 15 microns should be sufficient to prevent the formation of cracks in the more brittle dielectric below.

Suitable crack resistant dielectric materials must have high elongation to break (defined as 1% strain or greater). Suitable materials include free standing polyimide films such as Dupont's Kapton-E and Kapton-H films (Wilmington, Del.), Ube Upilex-S (Tokyo, Japan), and polyimides which are applied as a liquid and then cured, liquid crystal polymer dielectrics (including Rogers Zyvex (Rogers, Conn.) and Gore BIAC (Elkton, Md.)), and other thin, crack-resistant dielectrics. Depending upon the material, these dielectrics may be applied and cured directly to the inner layers of the substrate, or can be laminated to the substrate with an adhesive material. This adhesive can be comprised of the same material as makes up the inner layers of the substrate, or can be another thermosetting or thermoplastic adhesive.

### EXAMPLES

Samples using either clad (typically copper) or unclad crack-resistant outer layer dielectric material on packages of any layer count (typical is 3, 5 and 7) with direct lamination as shown in FIGS. 3 and 4.

FIG. 3 is a schematic representation of one possible interconnect substrate in combination with which the invention herein described may be used. FIG. 3 shows a 7-layer interconnect substrate 300 made by laminating an alternating series of conductive layers (320, 325, 330, 335, 340, 345, and 350) and dielectric layers (361, 362, 363, 364, 365 and 366). The conductive and dielectric layers shown in FIG. 3 are disposed symmetrically about a core conductive layer 335. That is, each dielectric or conductive layer formed on one side of core layer 335 has a corresponding layer of the same material formed on the opposite side of the core layer.

Disclosed are integrated circuit packages, which offer increased reliability in thermal cycle testing by incorporating a unique dielectric material as the outer dielectric layers 361 and 366. These dielectric layers may be formed dielectric materials that have high elongation to break (defined as 1% or greater strain). Included among the materials with high elongation to break are polyimides (including Dupont Kapton-E, Dupont Kapton-H, Ube Upilex-S), LCP dielectrics (including Rogers Zyvex LCP film and Gore BIAC LCP film), and other thin, crack-resistant dielectrics.

The dielectric layers 362, 363, 364, and 365 may be formed from laminates of high-temperature organic dielectric substrate materials, such as polyimides and polyimide laminates, epoxy resins, liquid crystal polymers, organic materials, or dielectric materials comprised at least in part of polytetrafluoroethylene, with or without a filler. In one preferred embodiment, dielectric layers 362, 363, 364, and 365 are made of an organic material such as polytetrafluoroethylene (PTFE), and more particularly, an expanded PTFE or “ePTFE” which is impregnated with cyanate ester and epoxy. The ePTFE material may be, in particular, an expanded polytetrafluoroethylene matrix containing a mixed cyanate ester-epoxy adhesive and inorganic filler.

Conductive layers 320 and 350 will include contact or bond pads such as those represented by 357 and 390 as well as possible additional routing traces (not shown). Solder balls (not shown) associated with the chip can be aligned over contact pads, 357, heated, and reflowed to form an electrical and mechanical bond with the contact pads on the die attach surface 304 of the interconnect substrate. Likewise, solder balls (not shown) associated with the board can be aligned over contact pads, 390, on the BGA attach surface 302 of the interconnect substrate, heated, and reflowed to form an electrical and mechanical bond between the contact pads and the PWB.

Conductive layers 320, 325, 330, 335, 340, 345, and 350 may be formed from a conductive material, such as copper. Other well-known conductive materials can also be used such as aluminum, gold, or silver. In this example, conductive layers 320, 325, 330, 340, 345, and 350 may each have a thickness in the range of approximately 5 to 14 microns. In one example, the thickness of each conductive layer 320, 325, 330, 335, 340, 345, and 350 is approximately 12 microns. The core conductive layer 335 may each have a thickness in the range of approximately 5 microns to about 50 microns. Dielectric layers 361, 362, 363, 364, 365 and 366 may each have a thickness in the range of approximately 20 microns to about 70 microns. In one example, the thickness of each dielectric 361, 362, 363, 364, 365 and 366 layer is approximately 36 microns.

The various layers of interconnect module 300 can be stacked together and laminated using heat and pressure. For example, all of the layers can be simultaneously laminated in a stack. Alternatively, the layers can be built upon a conductive core layer 335 one at a time, and incrementally built with one or two additional layers added in each lamination step. During lamination, dielectric layers 361, 362, 363, 364, 365 and 366 melt and flow to provide a monolithic bulk dielectric material.

FIG. 3 shows a first via 380 extends through dielectric layer 361 from conductive metal layer 320 terminates at conductive layer 325. A second via 375 begins at conductive layer 325 and extends through dielectric layers 362, 363, 364 and 365, and terminates at conductive layer 345. A third via 370 extends through dielectric layer 366 from conductive metal layer 345 and terminates at conductive layer 350. These vias may be created by laser drilling or laser ablation through the dielectric layers at the appropriate stage during the laminate build-up process. Each via 370, 375, 380 is plated with conductive material using any of the deposition techniques that are well known in the microelectronic fabrication art. Alternatively, each via 370, 375, 380 is filled with an electrically conductive material to define a conductive path. One skilled in the art will recognize that any combination of vias can be used to provide electrical connections between the bond pads 357 on the die attach surface 304 and the bond pads 390 on the BGA attach surface 302, including blind vias, buried vias and through vias.

Through vias can be formed following lamination of interconnect module 300. In particular, vias can be formed by drilling or laser ablation processes as described, for example, in U.S. Pat. No. 6,021,564, the entire content of which is incorporated herein by reference.

In some embodiments, interconnect module 300 may accept a “flip-chip” integrated circuit. Flip-chip mounting entails placing solder balls on a die or chip, flipping the chip over, aligning the chip with the contact pads on a substrate, such as interconnect module 300, and reflowing the solder balls in a furnace to establish bonding between the chip and the substrate. In this manner, the contact pads are distributed over the entire chip surface rather than being confined to the periphery as in wire bonding and tape-automated bonding (TAB) techniques. As a result, the maximum number of I/O and power/ground terminals available can be increased, and signal and power/ground interconnections can be more efficiently routed on the chips.

It should be recognized by those skilled in the art that interconnect substrates of the type reflected in the above embodiment may contain additional layers including embedded capacitor layers, conductive layers, dielectric layers and the like. It is also possible to make interconnect substrates having fewer dielectric and conductive layers depending on the requirements of the final interconnect module.

FIG. 4 is a schematic representation of one possible interconnect substrate in combination with which the invention herein described may be used. FIG. 4 shows a 5-layer interconnect substrate 400 made by laminating an alternating series of conductive layers (420, 425, 430, 435, and 440) and dielectric layers (461, 462, 463, and 464). The conductive and dielectric layers shown in FIG. 4 are disposed symmetrically about a core conductive layer 430. That is, each dielectric or conductive layer formed on one side of core layer 430 has a corresponding layer of the same material formed on the opposite side of the core layer.

Disclosed are integrated circuit packages, which offer increased reliability in thermal cycle testing by incorporating a unique dielectric material as the outer dielectric layers 461 and 464. These dielectric layers may be formed dielectric materials that have high elongation to break (defined as 1% or greater strain) on the outer layers of the package. Included among materials with high elongation to break are polyimides (including Dupont Kapton-E, Dupont Kapton-H, Ube Upilex-S), LCP dielectrics (including Rogers Zyvex LCP film and Gore BIAC LCP film), and other thin, crack-resistant dielectrics.

The dielectric layers 462 and 463 may be formed from laminates of high-temperature organic dielectric substrate materials, such as polyimides and polyimide laminates, epoxy resins, liquid crystal polymers, organic materials, or dielectric materials comprised at least in part of polytetrafluoroethylene, with or without a filler. In one embodiment, dielectric layers 462 and 463 are made of an organic material such as polytetrafluoroethylene (PTFE), and more particularly, an expanded PTFE or “ePTFE” which is impregnated with cyanate ester and epoxy. The PTFE material may be, in particular, an expanded polytetrafluoroethylene matrix containing a mixed cyanate ester-epoxy adhesive and inorganic filler.

Conductive layers 420 and 440 will include contact or bond pads such as those represented by 457 and 490 as well as possible additional routing traces (not shown). Solder balls (not shown) associated with the chip can be aligned over contact pads, 457, heated, and reflowed to form an electrical and mechanical bond with the contact pads on the die attach surface 404 of the interconnect substrate. Likewise, solder balls (not shown) associated with the board can be aligned over contact pads, 490, on the BGA attach surface 402 of the interconnect substrate 400, heated, and reflowed to form an electrical and mechanical bond between the contact pads and the PWB.

Conductive layers 420, 425, 430, 435, and 440 may be formed from a conductive material, such as copper. Other well-known conductive materials can also be used such as aluminum, gold, or silver. In this example, conductive layers 420, 425, 430, and 440 may each have a thickness in the range of approximately 5 microns to about 14 microns. In one example, the thickness of each conductive layer 420, 425, 430, 435, and 440 is approximately 12 microns. The core conductive layer 430 may each have a thickness in the range of approximately 5 microns to about 50 microns. Dielectric layers 461, 462, 463, and 464 may each have a thickness in the range of approximately 20 microns to about 70 microns. In one example, the thickness of each dielectric 461, 462, 463, and 464 layer is approximately 36 microns.

The various layers of interconnect module 400 can be stacked together and laminated using heat and pressure. For example, all of the layers can be simultaneously laminated with another in a stack. Alternatively, the layers can be built upon a conductive core layer 430 one at a time, and incrementally built with one or two additional layers added in each lamination step. During lamination, dielectric layers 461, 462, 463, and 464 melt and flow to provide a monolithic bulk dielectric material.

FIG. 4 shows a first via 480 and extends through dielectric layer 461 from conductive metal layer 420 and terminates at conductive layer 425. A second via 475 begins at conductive layer 425 and extends through dielectric layers 462 and 463, and terminates at conductive layer 435. A third via 470 extends through dielectric layer 464 from conductive metal layer 435 and terminates at conductive layer 440. These vias may be created by laser drilling or laser ablation through the dielectric layers at the appropriate stage during the laminate build-up process. Each via 470, 475, 480 is plated with conductive material using any of the deposition techniques that are well known in the microelectronic fabrication art. Alternatively, each via 470, 475, 480 is filled with an electrically conductive material to define a conductive path. One skilled in the art will recognize that any combination of vias can be used to provide electrical connections between the bond pads 457 on the die attach surface 404 and the bond pads 490 on the BGA attach surface 402, including blind vias, buried vias and through vias.

Through vias can be formed following lamination of interconnect module 400. In particular, vias can be formed by drilling or laser ablation processes as described, for example, in U.S. Pat. No. 6,021,564, the entire content of which is incorporated herein by reference.

In some embodiments, interconnect module 400 may accept a “flip-chip” integrated circuit. Flip-chip mounting entails placing solder balls on a die or chip, flipping the chip over, aligning the chip with the contact pads on a substrate, such as interconnect module 400, and reflowing the solder balls in a furnace to establish bonding between the chip and the substrate. In this manner, the contact pads are distributed over the entire chip surface rather than being confined to the periphery as in wire bonding and tape-automated bonding (TAB) techniques. As a result, the maximum number of I/O and power/ground terminals available can be increased, and signal and power/ground interconnections can be more efficiently routed on the chips.

It should be recognized by those skilled in the art that interconnect substrates of the type reflected in the above embodiment may contain additional layers including embedded capacitor layers, conductive layers, dielectric layers and the like. It is also possible to make interconnect substrates having fewer dielectric and conductive layers depending on the requirements of the final interconnect module.

FIG. 6 is a schematic representation of one possible interconnect substrate in combination with which the invention herein described may be used. FIG. 6 shows a 7-layer interconnect substrate 600 made by laminating an alternating series of conductive layers (620, 625, 630, 635, 640, 645, and 650), dielectric layers (661, 662, 663, 664, 665 and 666) and dielectric adhesive layers (668 and 669). The conductive and dielectric layers shown in FIG. 6 are disposed symmetrically about a core conductive layer 635.

Disclosed are integrated circuit packages, which offer increased reliability in thermal cycle testing by incorporating a unique dielectric material on the outer layers. The crack resistant dielectric layers 661 and 666 may be formed dielectric materials that have high elongation to break (defined as 1% or greater strain) on the outer layers of the package. Included among materials with high elongation to break are polyimides (including Dupont Kapton-E, Dupont Kapton-H, Ube Upilex-S), LCP dielectrics (including Rogers Zyvex and Gore BIAC), and other thin, crack-resistant dielectrics.

The crack resistant dielectric layers 661 and 666 may be adhesively bonded to the interconnect substrate laminate using a dielectric adhesive layer 668 and 669. The dielectric adhesive layer may be either a thermoplastic material, such as LCP, polyethylene terephthalate, polybutylene terephthalate or PTFE, or a thermosetting material such as an expanded PTFE or “ePTFE” which is impregnated with cyanate ester and epoxy, epoxy-based, cyanate ester-based, bis-maleimide-based, triazine-based, or polyimide adhesive. Inorganic fillers may be added to the dielectric adhesive to reduce the material's CTE and control its flow properties The dielectric layers 662, 663, 664, and 665 may be formed from laminates of high-temperature organic dielectric substrate materials, such as polyimides and polyimide laminates, epoxy resins, liquid crystal polymers, organic materials, or dielectric materials comprised at least in part of polytetrafluoroethylene, with or without a filler. In one embodiment, dielectric layers 662, 663, 664, and 665 are made of an organic material such as polytetrafluoroethylene (PTFE), and more particularly, an expanded PTFE or “ePTFE” which is impregnated with cyanate ester and epoxy. The PTFE material may be, in particular, an expanded polytetrafluoroethylene matrix containing a mixed cyanate ester-epoxy adhesive and inorganic filler.

Conductive layers 620, 625, 630, 635, 640, 645, and 650 may be formed from a conductive material, such as copper. Other well-known conductive materials can also be used such as aluminum, gold, or silver. In this example, conductive layers 620, 625, 630, 640, 645, and 650 may each have a thickness in the range of approximately 5 microns to about 14 microns. In one example, the thickness of each conductive layer 620, 625, 630, 635, 640, 645, and 650 is approximately 12 microns. The core conductive layer 635 may each have a thickness in the range of approximately 5 microns to about 50 microns. Dielectric layers 661, 662, 663, 664, 665 and 666 may each have a thickness in the range of approximately 20 microns to about 70 microns. In one example, the thickness of each dielectric 661, 662, 663, 664, 665 and 666 layer is approximately 36 microns.

The various layers of interconnect module 600 can be stacked together and laminated using heat and pressure. For example, all of the layers can be simultaneously laminated with another in a stack. Alternatively, the layers can be built upon a conductive core layer 635 one at a time, and incrementally built with one or two additional layers added in each lamination step. During lamination, dielectric layers 661, 662, 663, 664, 665 and 666 melt and flow to provide a monolithic bulk dielectric material 660.

As further shown in FIG. 6, a first via 680 extends through dielectric layer 661 from conductive metal layer 620 and terminates at conductive layer 625. A second via 675 begins at conductive layer 625 and extends through dielectric layers 662, 663, 664 and 665, and terminates at conductive layer 645. A third via 670 extends through dielectric layer 666 from conductive metal layer 645 and terminates at conductive layer 650. Each via 670, 675, 680 is plated with conductive material using any of the deposition techniques that are well known in the microelectronic fabrication art. Alternatively, each via 670, 675, 680 is filled with an electrically conductive material to define a conductive path. One skilled in the art will recognize that any combination of vias can be used to provide electrical connections between the bond pads 657 on the die attach surface 604 and the bond pads 690 on the BGA attach surface 602, including blind vias, buried vias and through vias.

Solder masks 610, 615 can be applied to chip attach surface 604 and BGA attach surface 602. Each solder mask 610, 615 exposes a contact or bond pad adjacent to each via 670, 675, 680. For example, solder mask 610 exposes contact pads 657, whereas solder mask 615 exposes contact pads 690. Solder balls (not shown) associated with the chip can be aligned over contact pads, 657 on the die attach side 604 of the interconnect substrate 600, heated, and reflowed to form an electrical and mechanical bond with the contact pads. Likewise, solder balls (not shown) associated with the board can be aligned over contact pads, 690 on the BGA side 602 of the interconnect substrate 600, heated, and reflowed to form an electrical and mechanical bond between the contact pads and the PWB.

Through vias can be formed following lamination of interconnect module 600. In particular, vias can be formed by drilling or laser ablation processes as described, for example, in U.S. Pat. No. 6,021,564, the entire content of which is incorporated herein by reference. Following lamination, solder masks 610 and 615 are added to interconnect module 600. Solder masks 610 and 615 are then patterned to define contact pads 657, 690, for receipt of solder balls from a chip 655 and PWB (not shown), respectively.

In some embodiments, interconnect module 600 may accept a “flip-chip” integrated circuit. Flip-chip mounting entails placing solder balls on a die or chip, flipping the chip over, aligning the chip with the contact pads on a substrate, such as interconnect module 600, and reflowing the solder balls in a furnace to establish bonding between the chip and the substrate. In this manner, the contact pads are distributed over the entire chip surface rather than being confined to the periphery as in wire bonding and tape-automated bonding (TAB) techniques. As a result, the maximum number of I/O and power/ground terminals available can be increased, and signal and power/ground interconnections can be more efficiently routed on the chips.

It should be recognized by those skilled in the art that interconnect substrates of the type reflected in the above embodiment may contain additional layers including embedded capacitor layers, conductive layers, dielectric layers and the like. It is also possible to make interconnect substrates having fewer dielectric and conductive layers depending on the requirements of the final interconnect module.

FIG. 7 shows the results finite element analysis model for an IC package that does not contain crack resistant outer dielectric layers. The graph shows the stress profile in the dielectric substrate as a function of distance away from a BGA bond pad. The data show that there is a significant increase in the stress at the surface of the outer most dielectric layer at the edge of the BGA bond pad and that this stress decreases with depth into the interconnect substrate. The stress also decreases quickly away from the edge of the bond pad. If this stress is greater than that needed for crack initiation, the resulting crack may propagate in such a manner that would reduce the reliability of the IC package as a whole.

Experimental results have generally agreed with the modeling. Two experiments have been completed with high elongation to break outer layer materials. A first experiment was carried out using a 40×40 mm substrate with a 10.6×12 mm die. In this experiment, a polyimide film was used on the outer layers and compared to control specimens, which contained outer layers made from a silica filled thermosetting adhesive having low (<0.5%) elongation to break. The samples with the polyimide film showed no cracks after 1500 air-to-air thermal cycles (−40° C. to 125° C.) while the specimens with low elongation outer layers showed cracks after as few as 500 cycles. A second experiment was conducted with a larger 45×45 mm package and a 17×17 mm die, and using a temperature cycling range of −55° C. to 125° C. Both the larger die size and the wider temperature range used in cycling make the stresses imparted to the package higher in this experiment, and increase the probability that cracking would occur in the outer layer dielectrics. In this experiment, a liquid crystal polymer dielectric was used on the outer layers and compared to control specimens having outer layers made from a silica filled thermosetting adhesive having low (<0.5%) elongation to break. The samples with the liquid crystal polymer showed no dielectric cracking after 1500 air-to-air thermal cycles (−55° C. to 125° C.) while the specimens with low elongation outer layers showed cracks after as few as 500 cycles.

What is claimed is:

1. An interconnect module providing conductive interconnection paths between an integrated chip, a printed wiring board, and at least one internal layer within said module, comprising a plurality of alternating dielectric and conductive layers laminated together to form a unitary structure having two outer layers, and said at least one internal layer, said module comprising a chip attach surface and a board attach surface, said surfaces defining contact pads for attachment to corresponding pads on the chip and printed wiring board, respectively, by means of solder balls, wherein said at least one internal layer is formed from an expanded polytetrafluoroethylene matrix impregnated with cyanate ester and epoxy, and at least one of said outer layers is formed from a high elongation dielectric material.

2. The interconnect module of claim 1 further comprising at least one conductive interconnection path selected from a via and a patterned signal layer.

3. The interconnect module of claim 1 wherein the expanded polytetrafluoroethylene material is an expanded polytetrafluoroethylene matrix containing a mixed cyanate ester-epoxy adhesive and inorganic filler.

4. The interconnect module of claim 1 wherein said at least one outer layer is formed from a material selected from the group consisting of polyimides and liquid crystal polymers.

5. The interconnect module of claim 1 wherein at least one of said outer layers is adhesively attached to an internal layer.

6. The interconnect module of claim 1 wherein said at least one outer layer is formed from a liquid crystal polymer.

7. The interconnect module of claim 1 further comprising a stiffening member that is bonded by an adhesive to an interconnection substrate on the chip attach surface such that the chip is centered within the stiffening member.

8. The interconnect module of claim 1 further comprising an underfill adhesive placed between the die attach surface and the bottom side of the integrated chip, encapsulating the solder balls.

9. The interconnect module of claim 1 further comprising a lid assembly bonded to the stiffening member by an additional adhesive layer.

10. The interconnect module of claim 8 further comprising a thermally conductive material selected from an adhesive or an elastomer interposed between a top surface of the chip and the lid assembly to assist in dissipating heat generated by the die during operation.

11. The interconnect module of claim 1 wherein no cracks form on the outer layers when the module is thermally cycled at from −40° C. to 125° C. for 1000 cycles.

12. The interconnect module of claim 1 wherein no cracks form on the outer layers when the module is thermally cycled at from −55° C. to 125° C. for 1000 cycles.

13. The interconnect of claim 10 wherein said outer layers have a thickness of from about 10 microns to about 50 microns.
